(19) United States
(12) Patent Application Publication
(10) Pub. No.: US 2016/0103396 A1
(43) Pub. Date: Apr. 14, 2016

(54) DOUBLE PATTERNING METHOD

(71) Applicant: UNITED MICROELECTRONICS CORP., Hsin-Chu City (TW)

(72) Inventors: En-Chiuan Liou, Tainan City (TW); Teng-Chin Kuo, Taipei (TW); Chun-Chi Yu, Taipei City (TW)

(21) Appl. No.: 14/512,484

(22) Filed: Oct. 13, 2014

(51) Int. Cl. G03F 7/20

(52) U.S. Cl. CPC G03F 7/70058

(57) ABSTRACT

A double patterning method comprises the following steps. First of all, a target layer and a mask layer stacked thereon are provided. Next, a first pattern opening is formed in the mask layer, and a width of the first pattern opening is measured to obtain a measuring value. Then, a second pattern opening is formed in the mask layer based on the measuring value, wherein the second pattern opening and the first pattern opening are co-planar. Finally, a bias trimming process is performed to trim the first pattern opening and the second pattern opening.

### BACKGROUND OF THE INVENTION

1. Field of the Invention

The present invention relates to a double patterning method, and more particularly, a double patterning method to form a line or a trench, which can immediately adjust the following patterning process via the inaccuracy of the prior patterning process in the same batch.

2. Description of the Prior Art

In recent years, with the increasing miniaturization of semiconductor devices, the line width and space between lines or devices becomes finer. The current method of forming the wiring structure includes forming a plug hole in a target layer, such a semiconductor material layer, and then sequentially forming various films in the plug hole. However, under requirements of continuous miniaturization, the current technique of forming the wiring structure, especially for double patterning method, also faces more challenges and limitations. For example, the current forming method is unable to form the plug hole in accurate size, thereby failing to meet the demand of the product.

Thus, there is a need of improved the currently forming method, to achieved the product demand through an easy and convenient process.

### SUMMARY OF THE INVENTION

It is one of the primary objectives of the present invention to provide a double patterning method, which can immediately adjust the following formed pattern opening via the inaccuracy of the prior formed pattern opening size in the same batch.

To achieve the purpose described above, the present invention provides a double patterning method comprising the following steps. First of all, a target layer and a mask layer stacked thereon are provided. Next, a first pattern opening is formed in the mask layer, and a width of the first pattern opening is measured to obtain a measuring value. Then, a second pattern opening is formed in the mask layer based on the measuring value, wherein the second pattern opening and the first pattern opening are co-planar. Finally, a bias trimming process is performed to trim the first pattern opening and the second pattern opening.

Through the present invention, the practical size (also known as the width) of the first pattern opening is measured immediately after the first pattern opening is formed, followed by immediately adjust the following formed second pattern opening via the inaccuracy of the first pattern opening in the same batch, thereby achieving the purpose of improving the accuracy of the entire device through an easy and convenient process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a flow chart illustrating a double patterning method according to a preferred embodiment of the present invention.

FIG. 2 to FIG. 8 are schematic diagrams illustrating cross-sectional views of the double patterning method according to a preferred embodiment of the present invention.

### DETAILED DESCRIPTION

To provide a better understanding of the present invention, preferred embodiments will be described in detail. The preferred embodiments of the present invention are illustrated in the accompanying drawings with numbered elements.

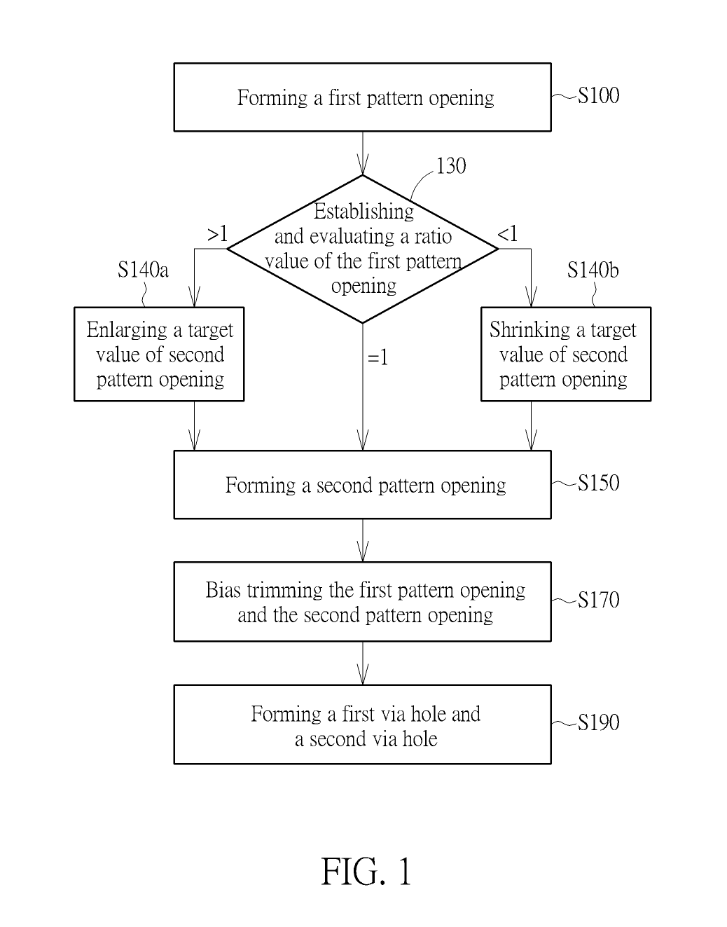

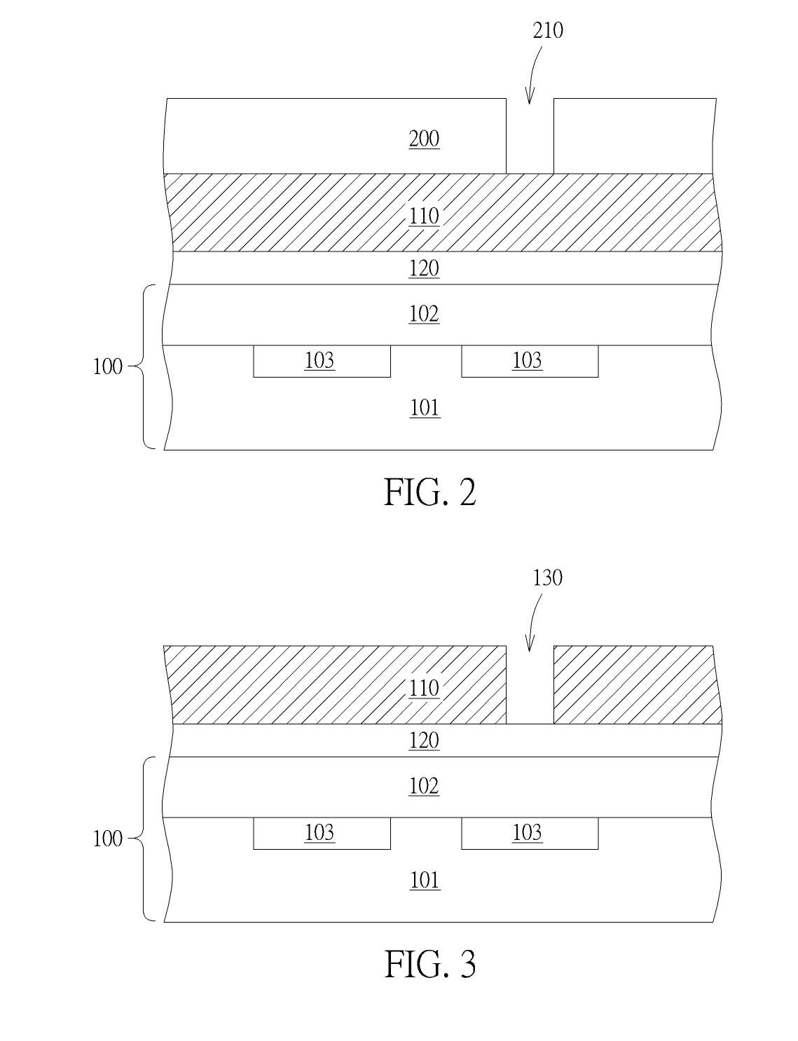

The present invention is related to a double patterning method which is used in a semiconductor process to form a semiconductor structure, such as a contact hole or a via hole, for immediately adjusting the following patterning process via the inaccuracy of the prior patterning process. Referring to FIGS. 1-8, a preferred embodiment of the double patterning method is exemplified, wherein FIG. 1 is a flow chart illustrating a double patterning method according to the preferred embodiment of the present invention, and FIGS. 2-8 are schematic diagrams illustrating various states of the double patterning method according to the preferred embodiment of the present invention.

As shown in FIG. 2-3, a target layer 100 and a mask layer 110 are stacked from bottom to top, and a first pattern opening 130 is formed (step S100) in the hark mask layer 110. The target layer 100 may include a single layered structure composed of a semiconductor material, such as a silicon substrate, an epitaxial silicon substrate, a silicon germanium substrate, a silicon carbide substrate, a silicon-on-insulator (SOI) substrate or a dielectric layer; or a multilayer structure composed of the aforementioned materials. In the present embodiment, the target layer 100 includes a dielectric layer 102 formed on another dielectric layer 101, wherein a conductive region 103 is formed in the dielectric layer 101 and the conductive region 103 maybe a portion of the metal interconnection system, such as a via plug or metal line, but the present invention is not limited thereto. In another embodiment, the target layer may also include a dielectric layer formed on a semiconductor substrate, wherein the conductive region formed in the dielectric layer may be any doping region or a gate electrode.

In addition, in a preferred embodiment, the first pattern opening 130 maybe formed by using a patterned first photoresist layer 200 as a mask. For example, the patterned first photoresist layer 200 including a single layer structure or a multilayer structure may be formed firstly on the mask layer 110 as shown in FIG. 2, and then, an pattern opening 210 of the patterned first photoresist layer 200 is then transferred to the mask layer 110 via an etching process, such as a dry etching. However, those in the art will be easy to realize that the first pattern opening 130 may also be formed through other suitable process. It is noted that, the patterned first photoresist layer 200 may have a first target value (T), and the first pattern opening 130 is basically formed in the mask layer 110 according to the first target value, but not limited thereto. In addition, in the present embodiment, an etching stop layer 120 may be formed between the target layer 100 and a mask layer 110, for example including dielectric material, such as silicon nitride, silicon carbide or silicon oxynitride, or conductive material, such that, the pattern opening 130 may be restricted in the mask layer 110. However, the present invention is not limited thereto, and in another embodiment of the present invention, the etching stop layer 120 may also be omitted.

Next, a ratio value of the first pattern opening 130 is established and evaluated (step S130). Precisely, after the first pattern opening 130 is formed, a width thereof is measured to obtain a first measuring value (M), such that the ratio value (M/T) may be established by comparing the measuring value (M) to the first target value (T). In addition, as shown in FIG. 1, if the ratio value (M/T) of the first pattern opening 130 is substantially equal to 1, namely, the measuring value (M) of the first pattern opening 130 is substantially equal to the first target value (T) of the first pattern opening 130, and then, a second pattern opening 140 may be formed directly (step S150) on the same plane to the first pattern opening 130, according to a second target value (T′). However, the present invention is not limited thereto, and in another embodiment, if the ratio value (M/T) of the first pattern opening 130 is not equal to 1, such as more than 1 or less than 1, which means that the measuring value (M) of the first pattern opening 130 may be either greater or less than the first target value (T) of the first pattern opening 130, an adjustable process is performed to immediately enlarge the second target value (T′) (step S140a) or to immediately shrink the second target value (T′) (step S140b) based on the ratio value (M/T) of the first pattern opening 130. Preferably, the adjustable process is performed while that the measuring value (M) of the first pattern opening 130 is at least 10% greater or 10% less than the first target value (T) of the first pattern opening 130, namely, the ratio value (M/T) of the first pattern opening 130 is preferably greater than 1.1 or less than 0.9, but not limited thereto.

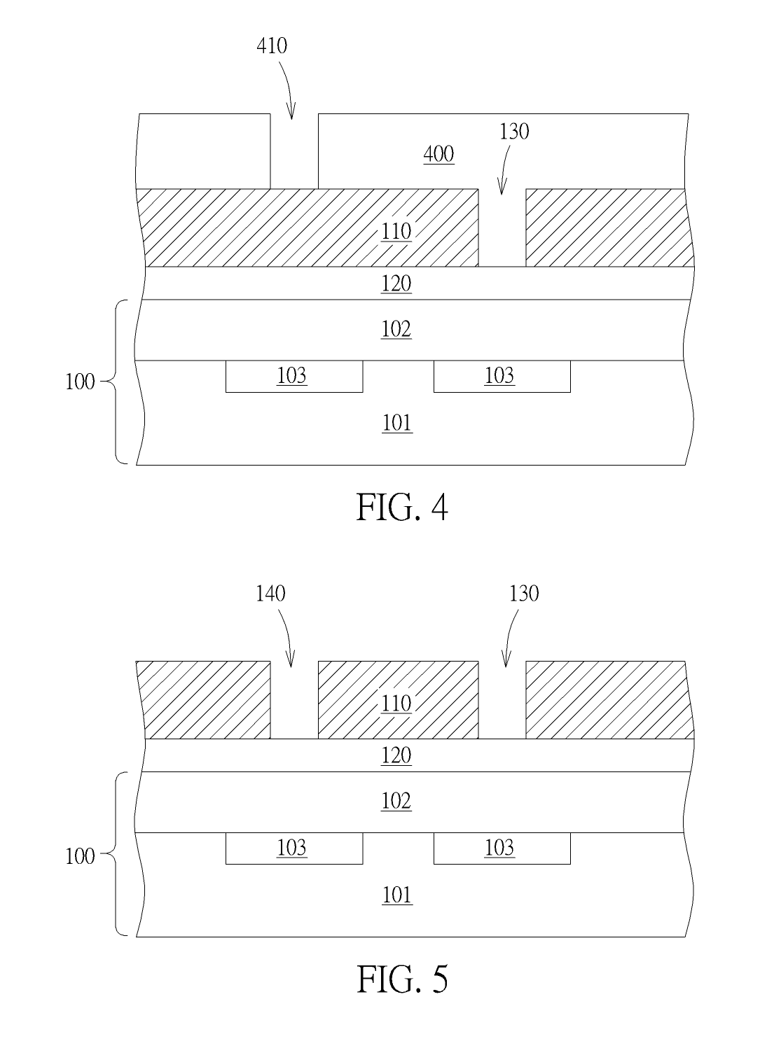

As shown in FIGS. 4-5, the second pattern opening 140 is formed (step S150) on the same plane similar to the method of forming the first pattern opening 130, through firstly providing a patterned second photoresist layer 400 (including a single layer structure or a multilayer structure), and transferring a pattern opening 410 of the second photoresist layer 400 to the mask layer 110 via an etching process, such as a dry etching. It is noted that, the second pattern opening 140 of the present embodiment is formed according to the measuring value (M) of the first pattern opening 130, such that the second pattern opening 140 may have adjusted size (also known as width) based on the first pattern opening 130. Precisely speaking, the patterned second photoresist layer 400 also has the second target value (T′), and however, once the ratio value (M/T) of the first pattern opening 130 being greater than 1, preferably greater than 1.1, is obtained, the second target value (T′) has to be adjustable immediately according thereto, such as enlarging the second target value (T′) accordingly. In this way, the second pattern opening 140 having a size (also known as width) greater than the second target value (T′) will be formed for example through modifying the parameters of photolithograph process, such as the litho-time while transferring the pattern opening 410 of the patterned second photoresist layer 400 according to the adjusted second target value (T′), but not limited thereto. In another embodiment, the second pattern opening 140 having the enlarged size (also known as width) may be formed by modifying the parameters of the etching process, such as the power supply of the dry etching, based on the adjusted second target value (T′). Similarly, if the ratio value (M/T) of the first pattern opening 130 being less than 1, preferably less than 0.9, is obtained, the second target value (T′) has to be adjustable immediately according thereto, such as shrinking the second target value (T′) accordingly, to form the second pattern opening 140 having a size (also known as width) less than the second target value (T′).

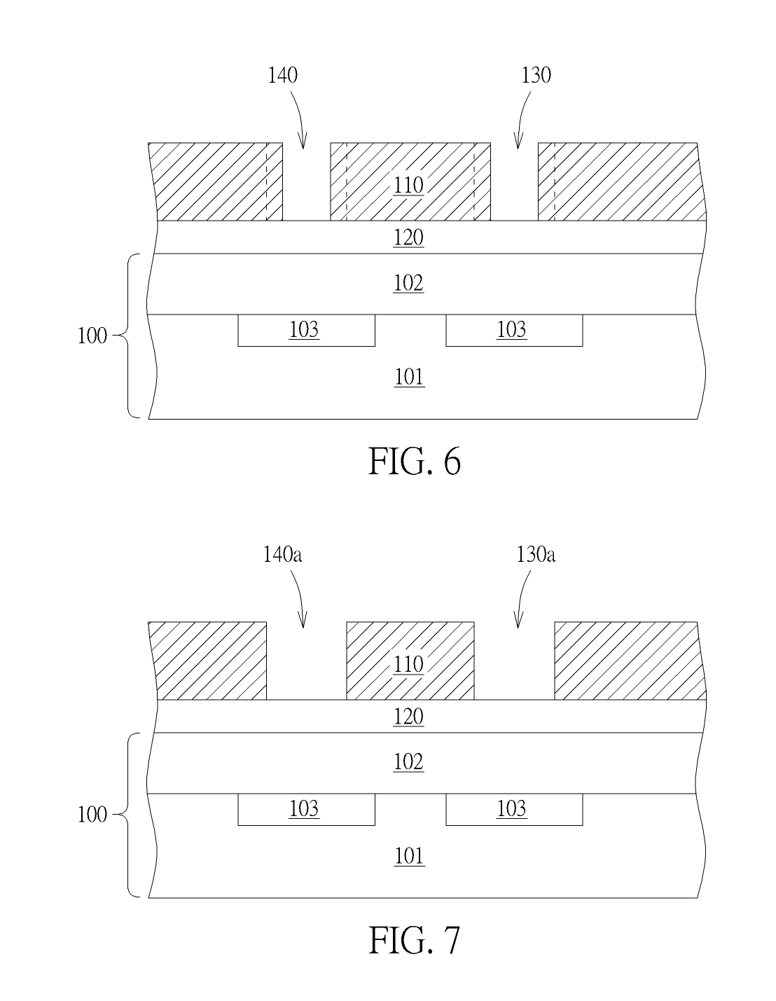

Next, as shown in FIG. 1 and FIG. 6, the first pattern opening 130 and the second pattern opening 140 are bias trimming simultaneously (step S170) and conformally. Precisely speaking, a lateral etching, such as a wet etching process or a dry etching, may be performed, to further trim the size (also known as the width) of the first pattern opening 130 and the second pattern opening 140 through laterally etching the side edges of the first pattern opening 130 and the second pattern opening 140 respectively. After that, an enlarged first pattern opening 130a and an enlarged second pattern opening 140a as shown in FIG. 7 are formed respectively. It is worth mentioning that, since the second pattern opening 140 is formed according to the measuring value (M) of the first pattern opening 130, both of the first pattern opening 130 and the second pattern opening 140 may have similar size ratio, and can be isotropically etched or lateral etched along the same direction through the same process. In other words, if the practical size (also known as the width) of the first pattern opening 130 is greater (less) than the target value (T), and then the second pattern opening 140 maybe formed also in a manner to have enlarged (shrunken) sized (also known as the width). Thus, both of the first pattern opening 130 and the second pattern opening 140 can have similar size ratio, and can be further trimmed in size (also known as the width) conformally in the present step, so as to form the first pattern opening 130a and the second pattern opening 140a shown in FIG. 7 simultaneously.

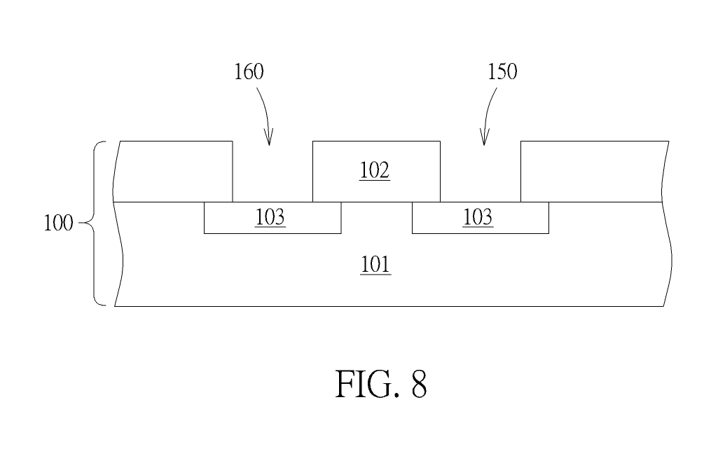

Finally, as shown in FIG. 8, the first pattern opening 130a and the second pattern opening 140a are then transferred to the target layer 100, to form a first plug hole 150 and a second plug hole 160 (step S190). Precisely, the first pattern opening 130a and the second pattern opening 140a of the present embodiment are transferred to the target layer 100 of the present embodiment, by using the mask layer 110 as an etching mask, to form the first plug hole 150 and a second plug hole 160 penetrated the dielectric layer 102 and directly contacted the conductive region 103 in the dielectric layer 101 as shown in FIG. 8. For example, at least one of the dry etching and wet etching process is performed, or the dry etching and wet etching process are performed sequentially, to progressively or one-off directly transfer the first pattern opening 130a and the second pattern opening 140a to the etching stop layer 120 and the target layer 100 underneath, to form the two plug holes 150, 160. Thus, the two plug holes 150, 160 may have the same layout pattern to the first pattern opening 130a and the second pattern opening 140a. After that, the mask layer 110 and the etching stop layer 120 are removed. Also, as following, the double patterning method may be integrated into a conventional metal structure process, to sequentially fill in barrier layer and metal layer. However, the present invention is not limited thereto, and in another embodiment, the two plug holes may also be formed through other suitable process known in the art and further integrated with other processes.

In summary, the double pattern method according to the present invention is specially used of forming lines or trenches. Through the present invention, the practical size (also known as the width) of the first pattern opening is measured immediately after the first pattern opening is formed, so as to directly adjust the following formed second pattern opening in the same batch via the inaccuracy of the first pattern opening. Accordingly, the present invention can immediately adjust the following formed pattern opening via the inaccuracy of the prior formed pattern opening in the same batch, thereby achieving the purpose of improving the accuracy of the entire device through an easy and convenient process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A double patterning method, comprising:
providing a target layer and a mask layer stacked thereon;
forming a first pattern opening in the mask layer;
measuring a width of the first pattern opening to obtain a measuring value;
forming a second pattern opening in the mask layer based on the measuring value, wherein the second pattern opening and the first pattern opening are co-planar; and
performing a bias trimming process to trim the first pattern opening and the second pattern opening.

2. The double patterning method according to claim 1, wherein the first pattern opening is formed based on a first target value.

3. The double patterning method according to claim 2, wherein the forming of first pattern opening further comprising:
forming a patterned first photoresist layer on the mask layer, based on the first target value; and
forming the first pattern opening by using the patterned first photoresist layer as a mask.

4. The double patterning method according to claim 2, wherein the second pattern opening is formed based on a ratio value between the measuring value and the first target value.

5. The double patterning method according to claim 4, wherein the forming of second pattern opening further comprising:
forming a patterned second photoresist layer on the mask layer, based on the ratio value; and
etching the mask layer to form the second pattern opening by using the patterned second photoresist layer as a mask.

6. The double patterning method according to claim 4, wherein the forming of second pattern opening further comprising:
forming a patterned second photoresist layer on the mask layer; and
etching the mask layer to form the second pattern opening based on the ratio value.

7. The double patterning method according to claim 4, wherein the second pattern opening has a width less than a second target value as the ratio value is less than 1.

8. The double patterning method according to claim 7, wherein the ratio value is less than 0.9.

9. The double patterning method according to claim 4, wherein the second pattern opening has a width greater than a second target value, as the ratio value is greater than 1.

10. The double patterning method according to claim 9, wherein the ratio value is greater than 1.1.

11. The double patterning method according to claim 1, wherein the bias trimming process, the width of the first pattern opening and a width of the second pattern opening are enlarged simultaneously and conformally.

12. The double patterning method according to claim 1, further comprising:
forming an etching stop layer between the target layer and the mask layer.

13. The double patterning method according to claim 1, further comprising:
forming a first plug hole and a second plug hole in the target layer via the first pattern opening and the second pattern opening respectively.
